(19) United States
(12) Patent Application Publication
(10) Pub. No.: US 2003/0031935 A1
(43) Pub. Date: Feb. 13, 2003

(54) Chromeless phase shift mask

(76) Inventor: Chi-Yuan Hung, Ilan Hsien (TW)

Correspondence Address: POWELL, GOLDSTEIN, FRAZER & MURPHY LLP, P.O. BOX 97223, WASHINGTON, DC, 20090-7223, US

(21) Appl. No.: 09/924,217

(22) Filed: Aug. 8, 2001

(51) Int. Cl. G03F 9/00; G03B 27/00; G03G 16/00

(52) U.S. Cl. 430/5; 355/18

(57) ABSTRACT

A Chromeless phase shift mask utilizes a line width control region having an incline phase shift structure located between a transparent region and a phase shift region and tapered from the edge of the phase shift layer to produce destructive interference of an incident radiation transmitted through the line width control region, and the intensity of the transmitted radiation is thereby decreased. Therefore, the line width of non-exposure region can be freely controlled by the line width control region and not restricted to the wavelength of the incident radiation.

### FIELD OF THE INVENTION

The present invention relates to semiconductor process equipment, and more particularly to a Chromeless phase shift mask (PSM) having preferable line width control in a photolithography process.

### BACKGROUND OF THE INVENTION

In the semiconductor industry, photolithographic exposure tools such as steppers and scanners have been used to define patterns in photosensitive material known as photoresist. After photoresist material is spun onto a substrate, an exposure tool repeatedly projects an image of the pattern that is defined on the mask to repeatedly expose the photoresist layer. The properties of the exposed portions of the photoresist layer are altered for subsequent processing steps such as resist development and consecutive substrate etching or implantation.

A mask is typically a transparent plate such as quartz with opaque elements such as chrome layer on the plate used to define a pattern. A radiation source illuminates the mask according to well-known methods. The radiation transmitted through the mask and exposure tool projection optics forms a diffraction limited latent image of the mask features on the photoresist layer. Further discussion of patterning principles and diffraction limited microlithography can be found on pages 274-276 of VLSI Technology edited by S.M. Sze (C) 1983)

However, because of increased semiconductor device complexity, which results in increased pattern complexity, increased resolution demands, and increased pattern packing density on the mask, distance between any two opaque areas has decreased. By decreasing the distances between the opaque areas, small apertures are formed which diffract the light that passes through the apertures. The diffracted light results in effects that tend to spread or to bend the light as it passes so that the space between the two opaque areas is not resolved, therefore masking diffraction a severe limiting factor for conventional optical photolithography.

As feature sizes decrease, semiconductor devices are typically less expensive to manufacture and have higher performance. In order to produce smaller feature sizes, an exposure tool having adequate resolution and depth of focus at least as deep as the thickness of the phtoresist layer is desired. For exposure tools that use conventional or oblique illumination, better resolution can be achieved by lowering the wavelength of the exposing radiation or by increasing the numerical aperture of the exposure tool, but the smaller resolution gained by increasing the numerical aperture is typically at the expense of a decrease in the depth of focus for minimally resolved features. This constraint presents a difficult problem in reducing the patterning resolution for a given radiation wavelength.

One method of printing smaller features with smaller critical dimensions while maintaining a sufficient depth of focus involves the use of phase shift mask (PSM). PSM uses phase shift elements, which shift the phase of the incident radiation to transmit radiation 180 degrees out of phase compared to radiation transmitted by adjacent mask elements. The radiation transmitted by the phase shift elements destructively interferes with radiation transmitted by adjacent mask elements in the areas of the image plane most susceptible to depth of focus limitations.

A method for dealing with diffraction effects in conventional photolithography is achieved by using a Chromeless phase shift mask (PSM), which replaces the previously discussed mask. Generally, with light being through of as a wave, phase shifting with a Chromeless phase shift mask is achieved by effecting a change in timing or by effecting a shift in waveform of a regular sinusoidal pattern of light waves that propagate through a transparent material. Typically, phase shifting is achieved by passing light through areas of a transparent material of either differing thickness or through materials with different refractive indexes, thereby changing the phase or the period pattern of the light wave. Chromeless PSM reduces diffraction effects by combining both phase shifted light and non-phase shifted light so that constructive and destructive interference takes place. Generally, a summation of constructive and destructive interference of Chromeless PSM results in improved resolution and in improved depth of focus of a projected image of an optical system.

Referring to FIG. 1, it is a schematic, cross-sectional view of the Chromeless PSM in accordance with the prior art. Thickness difference of a phase shift region 14 to a transparent region 12 is employed in a Chromeless PSM 10 to shift the phase of incident radiation. Generally, the type of Chromeless PSM is made of quartz, and the thickness of quartz in the phase shift region 14 is thicker than the transparent region 12. The boundary 16 between the transparent region 12 and phase shift region 14 is rectangularity. The radiations passing through the transparent region 12 and phase shift region 14 destructively interfere to form a restrictedly narrow line in the boundary 16.

However, only one fixed wavelength of illumination source is provided in each photolithographic exposure machine. Therefore, the conventional Chromeless PSM only can provide a fixed narrow line without modification. For specific electronic products, such as logic products, different line widths are required in one electronic layout, especially for iso-line that is distant from other conductive lines. Hence, the conventional Chromeless PSM cannot achieve the requirement of providing different width of conductive lines in one mask pattern.

### SUMMARY OF THE INVENTION

Therefore, the present invention provides a Chromeless phase shift mask (PSM), which can includes different line widths in one mask pattern, especially for iso-lines.

The present invention provides a Chromeless PSM which comprising a transparent region, a phase shift region and a line width control region. The transparent region is used for transmitting an incident radiation. The phase shift region is used for transmitting the incident radiation, and the transmitted radiation has a phase delay of 180 degrees relative to the incident radiation. The line width control region including an inclined structure is located between the transparent region and phase shift region, and produces destructive interference to the incident radiation that transmitted through the line width control region. Since the line width control region is set, the exposed line width can be therefore adjusted to different requirement.

The present invention also provides a Chromeless PSM which comprising a base transparent layer, a phase shift layer, and a line width control layer. The base transparent layer is used for transmitting an incident radiation. The phase shift layer is deposed on the base transparent layer. The phase shift layer is used for transmitting the incident radiation and the transmitted radiation has a phase delay of 180 degrees relative to the incident radiation. The line width control layer with an incline structure tapered from the edge of the phase shift layer is deposed on the base transparent layer and adjacent to the edge of the phase shift layer. The line width control layer produces destructive interference to the incident radiation that transmitted through the line width control region.

The present invention also provides a photolithographic exposure equipment, which at least comprises an illumination system, a chromeless phase shift mask and a project system. The illumination system is used for illuminating an incident radiation. The chromeless phase shift mask is used for shielding a portion of the incident radiation to form a latent pattern. The project system is used for projecting the latent pattern to a photosensitive layer on a wafer. Wherein, chromeless phase shift mask comprises a transparent region, a phase shift region, and a line width control region. The transparent region and the phase shift region are used for transmitting the incident radiation, and the transmitted radiation in the phase shift region has a phase delay of 180 degrees relative to the incident radiation. The line width control region including an inclined structure is located between the transparent region and phase shift region, and produces destructive interference to the incident radiation that transmitted through the line width control region.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic cross-sectional view of Chromeless phase shift mask (PSM) in accordance with the prior art;

FIG. 2a is a schematic cross-sectional view of Chromeless phase shift mask according to the present invention;

FIG. 2b is a diagram illustrating transmission function of the Chromeless PSM according to the present invention;

FIG. 2c is a diagram illustrating electric field distribution of transmission radiation passing through the Chromeless PSM according to the present invention;

FIG. 2d is a diagram illustrating intensity of the transmission radiation passing through the Chromeless PSM according to the present invention; and

FIG. 3 is a schematic view of the photolithographic exposure equipment according to the present invention.

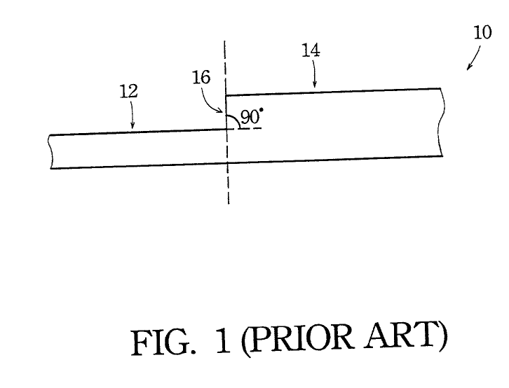

### Detailed DESCRIPTION OF THE PREFERRED EMBODIMENT

The present invention provides a Chromeless phase shift mask (PSM). A line width control region having an incline structure is formed between a transparent region and a phase shift region to produce destructive interference to an incident radiation transmitted through the line control region. The line width of non-exposure region on a photoresist layer can be freely selected by controlling the width of line width control region on the Chromeless PSM, especially for iso-lines to provide flexibility of electronic layout.

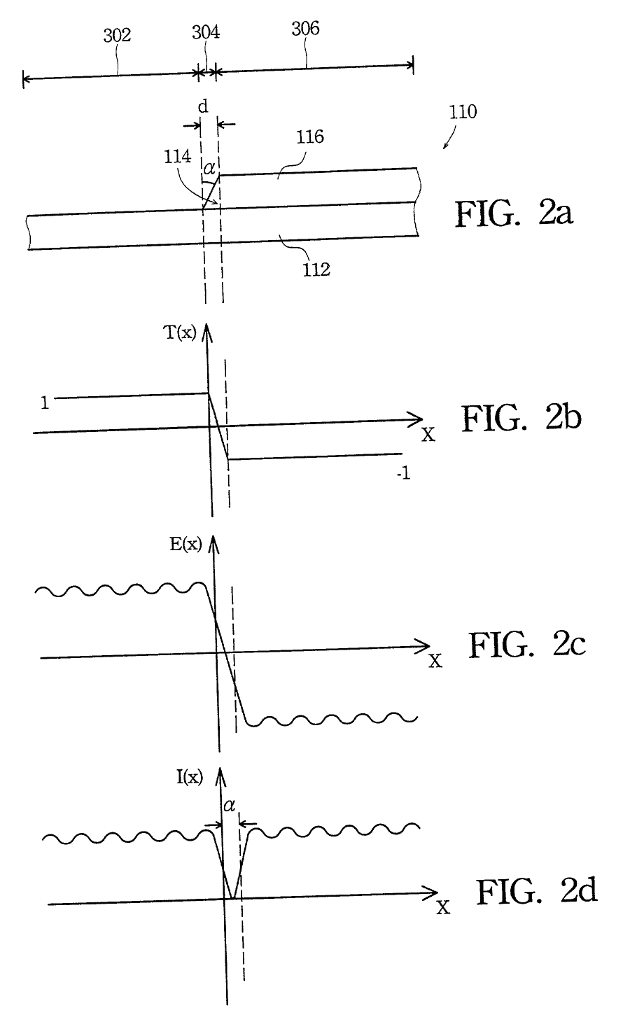

Referring to FIG. 2a, it is a schematic cross-sectional view of Chromeless PSM according to the present invention. The Chromeless PSM of the present invention comprises a base transparent layer 112 which can be made of a material with high transparency, such as quartz, to transmit an incident radiation. A phase shift layer 116 disposed on the base transparent layer 112 is used for transmitting an incident radiation, and makes the incident radiation transmitted through the phase shift layer 116 have a phase delay relative to the incident radiation. Generally, the phase delay of transmitted radiation is 180 degrees to be opposite to the incident radiation. A line width control layer 114 is located on the base transparent layer 112 and on the edge of the phase shift layer 116. The line width control layer 114 is a phase shift material layer with an incline structure that is tapered from the edge of the phase shift layer 116. The line width control layer 114 has a width d and an angle α relative to the vertical axis of the base transparent layer 1 12. The desired line width on the photoresist layer can be freely selected by controlling the width d of the line width control layer 114 on the Chromeless PSM 110. The phase shift layer 116 and line width control layer 114 can be formed of a material the same as the transparent layer 112, such as quartz, to achieve the function of phase shifting by utilizing thickness difference. Similarly, the phase shift layer 116 and line width control layer 114 also can be formed of other phase shift material to achieve phase shifting by utilizing refractive index difference.

On another aspect, the Chromeless PSM 110 of the present invention comprises a transparent region 302, a phase shift region 306, and a line width control region 304 between the transparent region 302 and phase shift region 306. The transparent region 302 comprising a transparent layer, such as a quartz layer, is used for transmitting the incident radiation. The phase shift region 306 comprising a phase shift layer, such as a quartz layer having different thickness to the layer in the transparent region 306, is used for transmitting the incident radiation, and makes the incident radiation transmitted through the phase shift region 306 have a phase delay relative to the incident radiation. Generally, the phase delay of transmitted radiation is 180 degrees to be opposite to the incident radiation. The line width control region 304 between the transparent region 302 and phase shift region 304 is an inclined phase shift material layer comprising a quartz layer. By radiation interference effect, the incident radiation transmitted through the line width control region 304 produces destructive interference, thereby decreasing intensity of the incident radiation.

FIG. 2b is a diagram illustrating transmission function of the Chromeless PSM according to the present invention. Referring to FIG. 2b, a Chromeless PSM employing quartz is used as an example. The incident radiation transmitted through the transparent region 302 is hold in original intensity and phase, and therefore the transmission value in the transparent region 302 is 1. The incident radiation transmitted through the phase shift region 306 has a phase delay of 180 degrees relative to the original incident radiation, i.e. is opposite to the original phase, thereby the transmission value in the phase shift region 306 is −1. The transmission value of incident radiation transmitted through the line control region 304 presents linear distribution between 1 and −1, as shown in FIG. 2b. Referring to FIG. 2c, it is a diagram illustrating electric field distribution of transmitted radiation passing through the Chromeless PSM of the present invention. The electric field of the radiation transmitted through the transparent region 302 is positive, and the electric field of the radiation transmitted through the phase shift region 306 is negative. The electric field of the radiation transmitted through the line control region 304 presents liner continuous between the transparent region 302 and phase control region 306. FIG. 2d is a diagram illustrating radiation intensity of transmitted radiation. The radiation intensity is proportioned to the square of electric field. Hence, the radiation intensities passing by the transparent region 302 and the phase shift region 306 are the same. However, the radiation transmitted through the line control region 304 produce destructive interference, and thus the radiation intensity in line control region 304 is greatly decreased. This results in that the radiation in the line control region is not enough to expose the photoresist layer. By controlling the width d of line control region, the width of non-exposure region on the photoresist layer can be freely selected, and not limited to the fixed line width in conventional Chromeless PSM. The present invention provides adjustable line width in Chromeless PSM and therefore being more convenient and flexible for electronic layout. The line control region 304 preferred adapted for iso-line that is about 2-3 times width distant from other conductive lines in some electronic product, such as logic product. Therefore, the radiation for iso-line will not be interfered with other lines, and the exposure result of line control region 304 will not be affected.

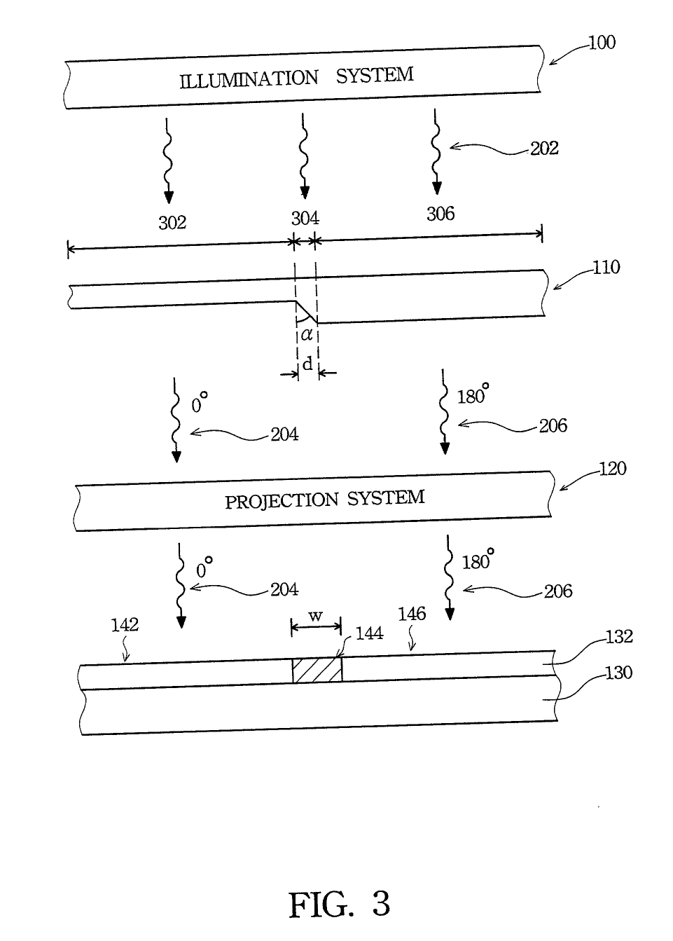

FIG. 3 is a schematic view of the photolithographic exposure equipment of the present invention. The photolithographic exposure equipment comprises an illumination system 100 for illuminating incident radiation 202. The illumination system 100 can be conventional illumination source. The wavelength of incident radiation 202 can be 436 nm, 365 nm, or 248 nm, even 193 nm. By destructively interfering in line width control region 304 to decrease radiation intensity of incident 9 radiation 202 while the incident radiation passing through the Chromeless PSM 110. Therefore, portion of the incident radiation 202 is shielded to form desired latent pattern. As shown in FIG. 3, the incident radiation 202 fully penetrates the transparent region 302 of Chromeless PSM 110 with original phase to be incident radiation 204. The incident radiation 202 penetrates the phase shift region 306 with opposite phase to be incident radiation 206. The incident radiation 202 transmitted through the line width control region 304 is decreased because of destructive interference.

Latent pattern is formed after the incident radiation 202 passing through the Chromeless PSM 110, and projected to a photosensitive layer 132 on a wafer 130 with a project system 120 to form a pattern on the photosensitive layer 132. The photosensitive layer 132 is composed of photoactive compound (PAC) to serve as a photoresist layer that is a mask in subsequent etching and ion implantation process. The photosensitive layer 132 is preferably composed of positive photoresist material. Since the incident radiations 204, 206 in the transparent region 302 and phase shift region 306 hold original radiation intensity, bright regions 142, 146, i.e. exposure regions, are formed on the photosensitive layer 132. In Contrast, The incident radiation 202 in the line width control region 304 is decreased by destructive interference, dark region 144, i.e. non-exposure region, is formed on the photosensitive layer 132. Since interference is also produced in the edge of the line width control region 304, the radiation intensity will be decayed, and thereby, the width w of the dark region 144 will be wider than the width d of the line control region 304. The present invention can freely select the line width w of pattern, i.e. width w of dark region 144, on the photosensitive layer 132 by controlling the width d of the line width control region 304. Using wavelength of 248 nm as an example, different line widths, such as 70 nm, 100 nm or 150 nm, even 250 nm, can be exposed on the photosensitive layer 132 by the Chromeless PSM 110. It is well known for a person skilled in the art to perform the following processes, and it will not be discussed furthermore.

According to above description, the Chromeless PSM of the present invention can provide a latent pattern with different line widths for the photosensitive layer to satisfy different requirements in layout and increase design capacity.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A Chromeless phase shift mask, comprising:
a transparent region for transmitting an incident radiation;
a phase shift region for transmitting and having a phase delay of 180 degrees relative to the incident radiation; and
a line width control region with an inclined structure being located between the transparent region and phase shift region to produce destructive interference to the incident radiation transmitted through the line width control region.

2. The mask according to claim 1, wherein wavelength of the incident radiation comprises 248 nm.

3. The mask according to claim 1, wherein the transparent region comprises a quartz layer.

4. The mask according to claim 1, wherein the phase shift region comprises a quartz layer.

5. The mask according to claim 1, wherein the line width control region comprises a quartz layer having an incline structure.

6. The mask according to claim 1, wherein the line width control region includes a width for controlling line width of a non-exposure region.

7. The mask according to claim 1, wherein the line width control region is adapted for fabricating an iso-line.

8. A Chromeless phase shift mask, comprising:
a base transparent layer for transmitting an incident radiation;
a phase shift layer for transmitting and have a phase delay of 180 degrees relative to the incident radiation being deposed on the base transparent layer; and
a line width control layer with an incline structure tapered from the edge of the phase shift layer being deposed on the base transparent layer and adjacent to the edge of the phase shift layer to produce destructive interference to the incident radiation transmitted through the line width control region.

9. The mask according to claim 8, wherein wavelength of the incident radiation comprises 248 nm.

10. The mask according to claim 8, wherein the transparent layer comprises a quartz layer.

11. The mask according to claim 8, wherein the phase shift layer comprises a quartz layer having different thickness to the transparent layer.

12. The mask according to claim 8, wherein the line width control layer comprises a quartz layer.

13. The mask according to claim 8, wherein the line width control layer has a width for controlling line width of a non-exposure region.

14. The mask according to claim 8, wherein the line width control region is adapted for fabricating an iso-line.

15. A photolithographic exposure equipment, at least comprising:
an illumination system for illuminating an incident radiation;
a chromeless phase shift mask for shielding a portion of the incident radiation to form a latent pattern; and
a project system for projecting the latent pattern to a photosensitive layer on a wafer;
wherein, the chromeless phase shift mask, comprising:
a transparent region for transmitting the incident radiation;
a phase shift region for transmitting and having a phase delay of 180 degrees relative to the incident radiation; and
a line width control region located between the transparent region and phase shift region producing destructive interference to the incident radiation transmitted through the line width control region to attenuate the intensity of the incident radiation.

16. The equipment according to claim 15, wherein wavelength of the incident radiation comprises 248 nm.

17. The equipment according to claim 15, wherein the latent pattern at least comprises an iso-line.

18. The equipment according to claim 15, wherein the transparent region comprises a quartz layer.

19. The equipment according to claim 15, wherein the phase transparent region comprises a quartz layer.

20. The equipment according to claim 15, wherein the line width control region comprises a quartz layer having an incline structure.

21. The equipment according to claim 15, wherein the line width control region includes a width for controlling line width of a non-exposure region.
